(19) United States
(12) Patent Application Publication
(10) Pub. No.: US 2013/0043594 A1
(43) Pub. Date: Feb. 21, 2013

(54) METHOD FOR MANUFACTURING SEMICONDUCTOR DEVICE AND SEMICONDUCTOR DEVICE

(71) Applicants: Yo Sasaki, Saitama-ken (JP); Atsushi Yamamoto, Kanagawa-ken (JP); Kazuya Kodani, Tokyo (JP); Yuji Hisazato, Tokyo (JP); Takashi Togasaki, Kanagawa-ken (JP); Hideaki Kitazawa, Kanagawa-ken (JP)

(72) Inventors: Yo Sasaki, Saitama-ken (JP); Atsushi Yamamoto, Kanagawa-ken (JP); Kazuya Kodani, Tokyo (JP); Yuji Hisazato, Tokyo (JP); Takashi Togasaki, Kanagawa-ken (JP); Hideaki Kitazawa, Kanagawa-ken (JP)

(73) Assignee: KABUSHIKI KAISHA TOSHIBA, Tokyo (JP)

(21) Appl. No.: 13/572,553

(22) Filed: Aug. 10, 2012

(30) Foreign Application Priority Data
Aug. 10, 2011 (JP) 2011-175075

(51) Int. Cl. H01L 21/50; H01L 23/482

(52) U.S. Cl. 257/762; 438/106; 257/765; 257/750; 257/E23.017; 257/E21.499

(57) ABSTRACT

According to one embodiment, between the mounting substrate and the semiconductor chip, there is a joint support layer including a metal or its alloy selected from the group of Cu, Al, Ag, Ni, Cr, Zr and Ti and a melt layer laminated across the joint support layer, and formed of a metal selected from the group of Sn, Zn and In or of an alloy of at least two metals selected from the same metals. The process of joining the mounting substrate and the semiconductor chip includes intervening a joining layer which is formed, at least for its outermost layer, by the melt layer, maintaining the temperature to be higher than the melting point of the melt layer, then forming an alloy layer which has a higher melting point than the melt layer by liquid phase diffusion.

### CROSS-REFERENCE TO RELATED APPLICATION

This application is based upon and claims the benefit of priority from Japanese Patent Application No. 2011-175075, filed Aug. 10, 2011; the entire contents of which are incorporated herein by reference.

### FIELD

Embodiments described herein relate to a method for manufacturing a semiconductor device and a semiconductor device.

### BACKGROUND

In general, in a semiconductor device, solder joints made of solder materials are used for the implementing techniques of semiconductor chips on mounting substrates. For these kinds of solder joint materials, Pb or Pb—Sn compounds are used, but due to the development of Pb-free compounds in recent years, Sn—Ag or Sn—Ag—Cu are now being used instead. Also, for a Si discrete type of semiconductor device, eutectic bonding formed by the reaction between Si and Au plating is used as a solder joint material.

In recent years, due to the miniaturization of electronic equipment, heat generation density of amounted semiconductor device has increased. Also, the general operating temperature of the Si semiconductor device is 125° C., so the device is used below 300° C., but compound semiconductor devices such as SiC or GaN can operate in a temperature which is higher than 300° C., which can result in solder bond failure under these high-temperature operating conditions where traditional lead based solder materials are used.

This is why an implementing technique with good heat resistance at 300° C. or higher and heat resistance cycle is desired for these higher operating temperature devices. For this kind of implementation, techniques such as low-temperature sintering with Ag nanoparticle or joints using an Au—Sn eutectic solder is put into use. However, the use of these materials has been limited because of the use of Au and Ag, which are considered precious metals.

Semiconductor chips are used in such a technique in order to obtain reliability under versatile and good high-temperature environments in order to enable high-temperature operations of the semiconductor device.

### DESCRIPTION OF THE DRAWINGS

FIG. 1 is a sectional view showing the joining process of a mounting substrate and a semiconductor chip in a semiconductor device according to a first embodiment.

FIGS. 2A to 2D are enlarged sectional views showing the joining process of the mounting substrate and the semiconductor chip in the semiconductor device according to the first embodiment in a part of the bonding layer.

FIG. 3 is a sectional view showing one aspect of the first embodiment.

FIGS. 4A and 4B are sectional views showing one aspect of the first embodiment.

FIGS. 5A and 5B are enlarged sectional views showing the joining process of a substrate and a semiconductor chip in a semiconductor device according to a second embodiment in a part of the bonding layer.

FIGS. 6A and 6B are enlarged sectional views showing the joining process of a substrate and a semiconductor chip in a semiconductor device according to a third embodiment in a part of the bonding layer.

FIG. 7 is a sectional view showing one aspect of the third embodiment

### DETAILED DESCRIPTION

In general, one embodiment will be explained by referring to the drawings.

According to the embodiment, the semiconductor chips are used in such a technique in order to obtain reliability under versatile and good high-temperature environments in order to enable high-temperature operations of the semiconductor device.

According to the manufacturing method of the semiconductor device involved in this embodiment, between the mounting substrate and the semiconductor chip, there is a joint support layer including a metal or its alloy selected from the group of Cu, Al, Ag, Ni, Cr, Zr and Ti, and a melt layer laminated across the joint support layer and formed of a metal selected from the group of Sn, Zn, and In or of an alloy of at least two metals selected from these metals. The process of joining the mounting substrate and the semiconductor chip includes intervening a joining layer which is formed, at least for its outermost layer, by the melt layer, maintaining the temperature to be higher than the melting point of the melt layer then forming a resulting alloy layer which has a higher melting point than the melt layer by liquid phase diffusion.

Also, the semiconductor device involved in this embodiment has a mounting substrate, a semiconductor chip joined on the mounting substrate, and a joining part including a joint-support layer including a metal or its alloy selected from the group of Cu, Al, Ag, Ni, Cr, Zr and Ti, at least one metal selected from the group of Sn, Zn and In, which will be provided across the joint support layer or an alloy layer, which has a metal included in the joint support layer, the joining part being provided between the mounting substrate and the semiconductor chip.

### Embodiment 1

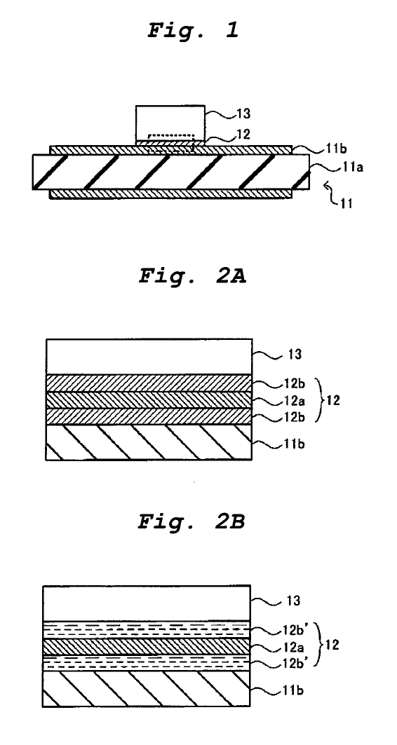

According to this embodiment, the semiconductor device is formed by joining the mounting substrate and the semiconductor chip as explained in the following. First, as shown in FIG. 1, for example, on the front side and the back side of insulating substrate 11a made of, e.g., SiN, on a predetermined position on wiring layer 11b of the mounting substrate 11 where a wiring layer 11b made of Cu is formed, after having formed the joining layer 12, semiconductor chip 13, for example, a SiC semiconductor chip, is placed.

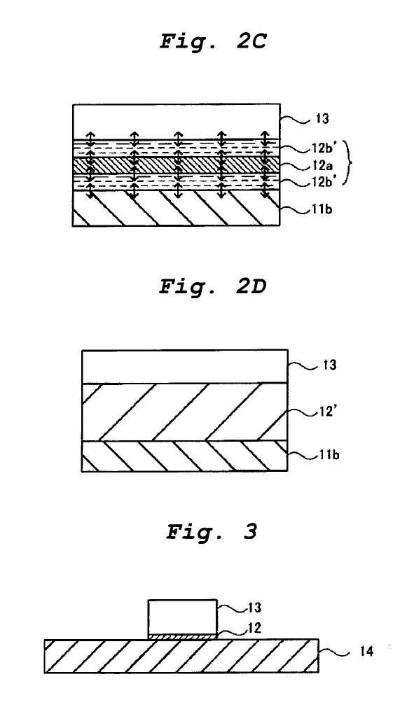

FIG. 2A is a dashed-line part of FIG. 1 showing an enlarged sectional view of a joining part. To enable a solder connection between the wiring layer 12, for example a bond pad, and the chip 13, joining layer 12 is formed over joint support layer 12a made of Cu, which is a high-melting point metal of 10 μm, a melt layer 12b which is a doubled layer made of Sn which is a low-melting point metal at 10 μm, are deposited. Joining layer 12 may, for example, be formed by a plating technique on wiring layer 11b by sequentially plating onto the wiring layer 11b the melt layer 12b, the joint support layer 12a and the melt layer 12b. Then, on the upper layer of melt layer 12b, the semiconductor chip 13 is placed.

Then, as shown in FIG. 2B, depending on the needs, for example, in an inert atmosphere, the mounting substrate 11 and the semiconductor chip 13 are held, while applying a predetermined pressure, and maintaining the joining layer 12 at a higher temperature than the melting point of melt layer 12b (the melting point of Sn: 232° C.). As a result, melt layer 12b (Sn layer) in its liquid state (melt layer 12b′) wets the mounting substrate 11 (wiring layer 11b) and the joining side of the semiconductor chip 13.

After that, as shown in FIG. 2C, by maintaining the layers 11 and 12 at or above the melting T of the Sn material for a predetermined period of time, the component (Cu) of wiring layer 11b and joint support layer 12a, interdiffuse, resulting in a Sn—Cu alloy or intermetallic compound having a higher melting T than the SN, such that the liquid phase of the melt layer 12b′ disappears.

By doing so, as shown in FIG. 2D, between the mounting substrate 11 and the semiconductor chip 13, joining part 12′ is formed by the alloy (intermetallic compound) layer including solid solution Cu and Sn, and the mounting substrate 11 and the semiconductor 13 are joined.

Joining part 12′ which has just been formed has a high melting point (the melting point of Cu₃Sn is about 700° C.) and can stabilize and allow the semiconductor device to function in a temperature which is higher than 300° C. Also, since precious metals are not used in the joining process, it is possible to mount versatile semiconductor chips at a low cost. In addition, because the melt layer 12b goes across joint support layer 12a, not only on the joining part of the mounting substrate 11 (wiring layer 11b) and the semiconductor chip 13, but also on both sides of joint support layer 12a, the mutual diffusion progresses, so it is possible for the mutual diffusion to occur in a shorter time.

In this embodiment, Cu is mentioned as a joint support layer 12a, but it is not limited to this material. As joint support layer 12a, it is good to form an alloy which has a melting point that is higher than 300° C. and the construction materials of melt layer 12b (metals that have a higher melting point than melt layer 12b). Apart from Cu, the choice can be made from among the metals Al, Ag, Ni, Cr, Zr, Ti or their alloys. An alloy such as Cu₃Sn which is an intermetallic compound of Cu and Sn can be used.

Also, Sn is mentioned as melt layer 12b but as melt layer 12b, apart from Sn, a binary alloy and ternary alloy compound made from Zn and In can also be used. For example, using the eutectic alloy In—Sn—Zn (eutectic temperature: 108° C.) enables a decrease in the joining temperature to 108° C., so it is possible to perform a joining process at a lower temperature.

Joint support layer 12a and melt layer 12b are, in the examples, 10 μm thick, but this thickness can be appropriately set between 0.1-100 μm, or more preferably 1-10 μm.

In this embodiment, SiN is mentioned as insulating substrate 11a of the mounting substrate 11, but apart from that, AlN and other substances can be used. Also, the mounting plate 11 is not limited to this kind of insulating substrate; it is possible to use a conductive substrate broadly used in the discrete type of semiconductor device. For example, as shown in FIG. 3, copper substrate 14 is used as the mounting substrate and the semiconductor chip 13 can also be joined through joining layer 12. In this case, as the copper substrate, not only a pure copper substrate but also copper alloy substrate, a copper-bonded substrate formed by bonding a copper plate of a copper alloy plate on the surface of an insulating substrate such as alumina, AlN, SiN and glass, can also be used.

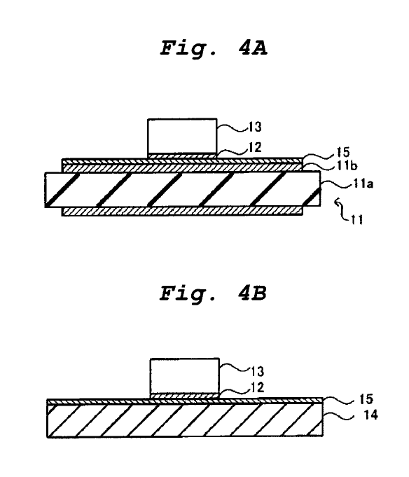

In addition, as shown in FIG. 4A and FIG. 4B, on top of wiring layer 11b of the mounting substrate 11 and on top of copper substrate 14, plating layer 15 which is made of Ag or Au can be provided. By providing this kind of plating layer 15, by suppressing the formation of an oxide film which forms a diffusion barrier, it is possible to reduce the formation of voids after joining; therefore, it is possible to improve the reliability of the joining process.

SiC semiconductor is mentioned as the semiconductor chip 13, but apart from that, it is possible to use not only an Si semiconductor but also compound semiconductor chips such as GaN and GaAs semiconductors. Also, the semiconductor chip is not particularly limited to the discrete type or module type.

Also, in this embodiment, joining layer 12 is formed by using the plating technique, but this forming technique of joining layer 12 is not limited; other thin film coating technologies such as sputtering technique, vacuum deposition technique and coating technique can also be used. It can also be formed by laminating a metal foil. In addition, after joining layer 12 is made of laminated metal foil structured in melt layer 12b/joint support layer 12a/and melt layer 12b, they are placed between the mounting substrate 11 and the semiconductor chip 13, then the joining process proceeds in the same way.

Also, in this embodiment, the mounting substrate 11 and the semiconductor chip 13 are heated in an inert atmosphere, while the components are pressed together, to form the alloy interconnecting the substrate 11 and chip 13. It is preferable to heat in an atmosphere without oxygen to minimize oxidation of the layers 12, or in a reducing atmosphere. In addition, as long as this pressure applied to force the chip 13 and substrate 11 together at the joining layer 12 is in a scope that does not damage the semiconductor chip, this pressure is not particularly limited; it is also possible to make use of a zero-pressure joining process so long as the chip 13 and substrate remain in contact during joining.

### Embodiment 2

This embodiment has the same kind of structure materials and joining process as the first embodiment, but when forming the joining layer and alloy layer, the fact that the joint support layer remains makes the difference.

In this embodiment, the semiconductor device is formed by joining a mounting substrate and a semiconductor chip as explained in the following. In the same way as in the first embodiment, on a predetermined position of the wiring layer 21b of the mounting substrate, after joining layer 22 is formed, the semiconductor chip 23 such as a SiC semiconductor chip is placed.

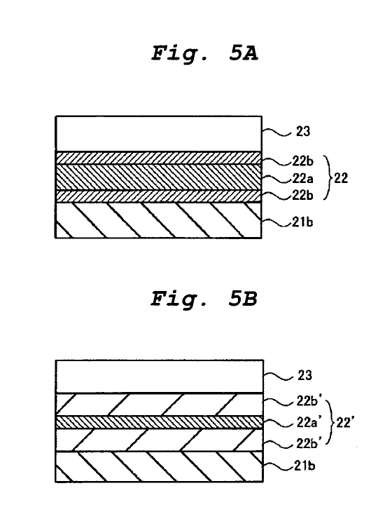

FIG. 5A shows an enlarged sectional view of the joining part. Joining layer 22, formed between wiring layer 21b on the mounting substrate and semiconductor chip 23, comprise, for example, joint support layer 22a made of Cu at 10 μm thickness, laminated between two melt layers 22b made of Sn at 5 μm thickness.

In the next step, in the same way as in the first embodiment, the mounting substrate and the semiconductor chip are held at above the melting point of melt layer 22b (melting point of Sn: 232° C.). Liquid phase of melt layer 22b and the mutual diffusion thereof are caused and the retention time is controlled appropriately. By doing this, as shown in FIG. 5B, an alloy layer 22b′ is formed on either side of the joint support layer 22a; A portion of Joint support layer 22a remains in situ, and the remaining part of this will join joint support layer 22a′ in order to form joining part 22′.

The joining part 22′, which has just been formed, as in the first embodiment, will have a high melting point which enables the stabilization of the semiconductor device and allows it to work even at a temperature higher than 300° C. Also, as in the first embodiment, since precious metals are not used for joining, it is possible to implement use of the versatile semiconductor chips at a low cost. In addition, embodiment, due to the fact that joint support layer 22a′ is inserted into melt layers 22b, as mutual diffusion progresses on both sides of joint support layer 22a, it is possible to have a mutual diffusion in a shorter time.

In addition, in the joining part 22′, joint support layer 22a′ remains, between the alloy layers 22b′ made of an intermetallic compound such as hard and brittle Cu₃Sn, joint support layer 22a′ made of highly deformable Cu remains, accordingly it is possible to relax the thermal stress due to the difference in the coefficient of linear expansion between the mounting substrate 21 and the semiconductor chip 23 during heat cycling of the chip 13 in use. Therefore, the occurrence of destruction due to the thermal stress of joining part 22′ and semiconductor chip 23 can be suppressed; it is possible to avoid the resulting decrease in reliability.

It should be noted that in this embodiment, the same construction materials and joining process as those in the first embodiment are applied, but for joint support layer 22a, in order to mitigate the thermal stress caused by the difference between the coefficient of linear expansion between the mounting substrate 21 and the semiconductor chip 23, apart from Cu, alloys such as Al, Ag, Cu—Zn can be suitably used. Also, in order to form joint support layer 22a′/alloy layer 22b′ as laminated structures, non-alloy materials which contains both a wiring layer and melt layer can be used in joint support layer 22a.

### Embodiment 3

In this embodiment, the same construction materials and joining process of Embodiment 1 are used but, for the joining layer, a joint support layer provided with multiple layers makes the difference.

In this embodiment, the semiconductor device formed by joining the mounting substrate and the semiconductor chip can be explained as follows. Just like the first embodiment, on the predetermined position of wiring layer 31b of the mounting substrate, after joining layer 32 has been formed, semiconductor chip 33, for example, SiC semiconductor chip, is placed.

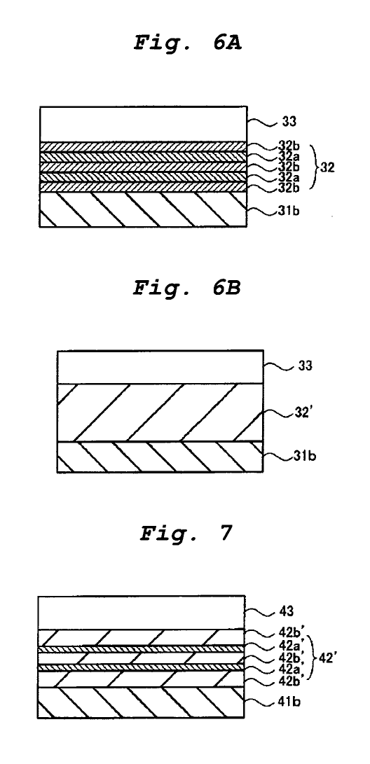

FIG. 6A shows an enlarged sectional view of the joining layer part. Regarding the joining layer 32, alternatively, joint support layer 32a can be doubled and melt layer 32b can be laminated in three layers, and melt layer 32b is formed in the outermost layer. The resulting structure, before heating, has two joint support layers32a, with a melt layer 32b sandwiched between the joint support layers 32a, and a melt layer disposed between the uppermost joint support layer and the chip 33, and a melt layer 32b between the lowermost joint support layer 32b and the support substrate 31b.

The next step is, as in the first embodiment, to maintain the temperature at higher than the melting point of melt layer 32b (the melting point of Sn: 232° C.) in order to cause the melt layers 32b to become a liquid-phase, and then cause mutual diffusion of melt layers 32b and bonding support layers 32a. By doing this, as shown in FIG. 6B, joining part 32′ is formed by solid solution or intermetallic alloy layer.

The joining part 32′ which just has been formed, as in the first embodiment, will have a high melting point which enables the stabilization of the semiconductor device and allows it to work even at a temperature higher than 300° C. Also, as in the first embodiment, since precious metals are not used for joining, it is possible to implement use of the versatile semiconductor chips at low cost.

In addition, due to the fact that joint support layer 32a and melt layer 32b are both laminated several times, because mutual diffusion progresses on both sides of joint support layer 22a, compared to the first embodiment, in the case where joining parts are formed at the same volume, it is possible to create the mutual diffusion of layers 32a, 32b in a shorter time.

It should be noted that, as in the second embodiment, as shown in FIG. 7, in the joining part 42′ provided between wiring layer 41b and the semiconductor chip 43, a portion of the original joint support layers, now joint support layers 42a inserted between alloy layers 42b′, may remain. Due to this, as in the second embodiment, it is possible to suppress the decrease in reliability by mitigating thermal stresses during heat cycling of the chip 43 in use.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device comprising the steps of:
between a mounting substrate and a semiconductor chip, preparing a joining layer including at least one first material selected from the group of Cu, Al, Ag, Ni, Cr, Zr and Ti or an alloy thereof, and positioning a second material selected from the group of Sn, Zn and In or of an alloy thereof on at least one side of the first material;
joining the mounting substrate and the semiconductor chip by maintaining the joining layer at a temperature higher than the melting point of the second material and less than the melting temperature of the first material, thereby forming an alloy layer of the first and second materials which has a higher melting point than the second material to thereby join the mounting substrate and semiconductor chip.

2. The manufacturing method of claim 1, wherein
at least a portion of the first material remains in place in a non-alloyed state with the second material after the alloy of the first and second materials is formed.

3. The manufacturing method of claim 1, wherein:
the second material is positioned on both sides of the first material prior to heating of the first and second materials to for the alloy thereof.

4. The manufacturing method of claim 2, wherein the first material is thicker than the second material prior to performing the step of heating of the first and second materials.

5. The manufacturing method of claim 4, wherein the portion of the first material remains in place in a non-alloyed state with the second material after the alloy of the first and second materials is formed provides a stress relief layer between the chip and the substrate.

6. The manufacturing method of claim 1, wherein a plurality of layers of the first material are located between a greater plurality of second material layers before the step of heating is performed.

7. The manufacturing method of claim 6, wherein:
after the step of heating the plurality of first and second material layers, a plurality of first material layers remain in place in a non-alloyed state with the second material, and an alloy of the first and second material is formed on either side of the remaining layers of the first material.

8. The manufacturing method of claim 7, wherein the plurality of first material layers remaining in place in a non-alloyed state with the second material form stress relief layers between the substrate and the chip.

9. The manufacturing method of claim 1, wherein, during the step of maintaining the joining layer at a temperature higher than the melting point of the second material and less than the melting temperature of the first material, the alloy of the first material and second material being formed has a higher melting point than the temperature at which the first and second layer are maintained.

10. The manufacturing method of claim 9, wherein, as the alloy between the first material and the second material is formed, the second material converts from a liquid state to a solid, alloyed with the first material, state.

11. The manufacturing method of claim 1, wherein a precious metal layer is formed between the alloy layer and at least one of the chip and the substrate.

12. A semiconductor device, comprising:
a mounting substrate;
a semiconductor chip joined on the mounting substrate; and
a joining part that includes:
a joint-support layer including any one of a material selected from the group of Cu, Al, Ag, Ni, Cr, Zr and Ti or an alloy thereof; and
an alloy layer that is provided between the mounting substrate and the semiconductor chip and that includes at least any one of a material selected from the group of Sn, Zn and In and the metal included in the joint-support layer.

13. The semiconductor device of claim 12, wherein the joining part includes at least two joint support layers, and an alloy layer on either side of each joint support layer.

14. The semiconductor device of claim 13, wherein the alloy layer has a higher melting temperature than the melting temperature of the second material.

15. The semiconductor device of claim 12, further including a precious metal layer located between at least one of the chip and the alloy layer, or the substrate and the alloy layer.

16. The semiconductor device of claim 12, wherein the joint support layer provides a stress relief layer between the chip and the substrate.

17. A semiconductor device, comprising:
a mounting substrate;
a semiconductor chip joined on the mounting substrate; and
an alloy layer joining the substrate and the chip, the alloy layer comprised of an alloy of:
any one of a first metal selected from the group of Cu, Al, Ag, Ni, Cr, Zr and Ti or an alloy thereof; and
any one of a second metal selected from the group of Sn, Zn and In.

18. The semiconductor device of claim 17, further including a stress relief layer disposed between the chip and the substrate.

19. The semiconductor device of claim 18, wherein the stress relief layer is positioned between alloy layers.

20. The semiconductor device of claim 19, wherein the stress relief layer, and the first metal of the alloy layer, are the same metal.
